(19) United States
(12) Patent Application Publication
(10) Pub. No.: US 2015/0206982 A1
(43) Pub. Date: Jul. 23, 2015

(54) THIN FILM TRANSISTOR FOR A DISPLAY DEVICE, DISPLAY DEVICE AND METHOD OF MANUFACTURING A DISPLAY DEVICE

(71) Applicant: Samsung Display Co., Ltd., Yongin-City (KR)

(72) Inventors: Sang-Ho MOON, Asan-si (KR); Sung-Ho KIM, Suwon-si (KR)

(21) Appl. No.: 14/547,955

(22) Filed: Nov. 19, 2014

(30) Foreign Application Priority Data
Jan. 22, 2014 (KR) 10-2014-0007792

(51) Int. Cl. H01L 29/786; H01L 29/423; H01L 21/02; H01L 29/417; H01L 27/12; H01L 29/66

(52) U.S. Cl. CPC H01L 29/78678; H01L 27/124; H01L 27/1259; H01L 27/1222; H01L 29/66765; H01L 21/02532; H01L 21/02592; H01L 21/02667; H01L 29/41733; H01L 29/42384; H01L 2029/42388

(57) ABSTRACT

A thin film transistor for a display device is disclosed. In one aspect, the thin film transistor includes a gate electrode formed over a substrate and including a first conductive pattern and a plurality of second conductive patterns. The thin film transistor also includes a semiconductor layer formed over the gate electrode, wherein the semiconductor layer is formed of a crystallized semiconductor material, a source electrode electrically connected to the semiconductor layer, and a drain electrode electrically connected to the semiconductor layer. The drain electrode is spaced apart from the source electrode in a first direction and the second conductive patterns at least partially overlap the first conductive pattern and are spaced apart from each other in the first direction.

### CROSS-REFERENCE TO RELATED APPLICATIONS

This application claims priority under 35 USC §119 to Korean Patent Application No. 10-2014-0007792 filed on Jan. 22, 2014 in the Korean Intellectual Property Office (KIPO), the disclosures of which are herein incorporated by reference in their entireties.

### BACKGROUND

1. Field

The described technology generally relates to a thin film transistor for a display device, a display device, and a method of manufacturing a display device.

2. Description of the Related Technology

Organic light-emitting diode (OLED) displays display information such as images and characters using light generated from an organic layer of each of the OLEDs formed therein. Light is generated through the combination of holes from an anode and electrons from a cathode at the organic layer interposed between the anode and the cathode. OLED displays have several advantages over other types of flat panel displays such as liquid crystal displays (LCDs), plasma display panels (PDPs), and field emission displays (FEDS). Examples of these advantages include wide viewing angle, fast response time, thin profile, and low power consumption. Accordingly, OLED displays are widely employed in various electrical and electronic apparatuses.

### SUMMARY OF CERTAIN INVENTIVE ASPECTS

One inventive aspect is a thin film transistor for a display substrate in an OLED display, a display substrate for an OLED display, and a method of manufacturing the same.

Another aspect is a thin film transistor for a display substrate having an improved reliability.

Another aspect is a display substrate having an improved reliability.

Another aspect is a method of manufacturing a display substrate having an improved reliability.

Another aspect is a thin film transistor for a display substrate. The thin film transistor includes a gate electrode, an active pattern, a source electrode and a drain electrode. The gate electrode is formed on a substrate and includes a first conductive pattern and a plurality of second conductive patterns. The active pattern is formed over the gate electrode. The active pattern includes a crystallized semiconductor material. The source electrode is electrically connected to the active pattern. The drain electrode is electrically connected to the active pattern. The drain electrode is spaced apart from the source electrode in a first direction parallel to a top surface of the substrate. The plurality of second conductive patterns are formed to overlap the first conductive pattern and are spaced apart from each other in the first direction.

In example embodiments, the plurality of second conductive patterns may be formed on the first conductive pattern.

In example embodiments, the plurality of second conductive patterns may be formed between the substrate and the first conductive pattern.

In example embodiments, the first conductive pattern and the second conductive patterns may have taper angles which are less than about 70°.

In example embodiments, the active pattern may include polysilicon which is formed by crystallizing amorphous silicon.

In example embodiments, the plurality of second conductive patterns may be electrically connected to each other by the first conductive pattern.

In example embodiments, the thin film transistor may further comprise a gate insulation layer between the gate electrode and the active pattern. Each of the first conductive pattern and the gate insulation layer may have a substantially uniform thickness.

In example embodiments, a top surface of the gate insulation layer may have stepped portions. A distance between the stepped portions may be less than a predetermined distance.

In example embodiments, the plurality of second conductive patterns may extend in a second direction substantially perpendicular to the first direction.

In example embodiments, the plurality of second conductive patterns may extend in a direction oblique to the first direction.

Another aspect is a display substrate. The display substrate includes a substrate, a first thin film on the substrate, and a second thin film electrically connected to the first thin film transistor. The first thin film transistor includes a first gate electrode, a first active pattern, a first source electrode, a first drain electrode. The first gate electrode is formed on the substrate. The first gate electrode includes a first conductive pattern and a plurality of second conductive patterns. The first active pattern is formed over the first gate electrode. The first active pattern includes a crystallized semiconductor material. The first source electrode is electrically connected to the first active pattern. The first drain electrode is electrically connected to the first active pattern. The first drain electrode is spaced apart from the first source electrode in a first direction parallel to a top surface of the substrate. The plurality of second conductive patterns are formed to overlap the first conductive pattern and are spaced apart from each other in the first direction.

In example embodiments, the display substrate may further comprises a gate line electrically connected to the first gate electrode of the first thin film transistor and a data line electrically connected to the first source electrode of the first thin film transistor.

In example embodiments, the second thin film transistor may include a second gate electrode, a second active pattern, a second source electrode and a second drain electrode. The second gate electrode may be on the substrate. The second gate electrode may include a third conductive pattern and a plurality of fourth conductive patterns. The second active pattern may be formed over the second gate electrode. The second active pattern may include a crystallized semiconductor material. The second source electrode may be electrically connected to the second active pattern. The second drain electrode may be electrically connected to the second active pattern. The second drain electrode may be spaced apart from the second source electrode in a second direction perpendicular to the first direction. The plurality of fourth conductive patterns may be formed to overlap the third conductive pattern and may be spaced apart from each other.

In example embodiments, the second active pattern may extend in the second direction and the plurality of fourth conductive patterns may be spaced apart from each other in the second direction.

Another aspect is a method of forming a display substrate. In the method, a gate electrode is formed on a substrate. The gate electrode has a top surface including stepped portion. A gate insulation layer is formed on the substrate to cover the gate electrode. An amorphous silicon layer is formed on the gate insulation layer. The amorphous silicon layer is crystallized to form a polysilicon layer. The polysilicon layer is partially removed to form an active pattern. A source electrode and a drain electrode are formed to be electrically connected to the active pattern. The source electrode and the drain electrode are spaced apart from each other in a first direction substantially parallel to a top surface of the substrate.

In example embodiments, forming the gate electrode may include forming a first conductive pattern on a substrate and forming a plurality of second conductive patterns to overlap the first conductive pattern.

Another aspect is a thin film transistor for a display device, including a gate electrode formed over a substrate and including a first conductive pattern and a plurality of second conductive patterns, a semiconductor layer formed over the gate electrode, wherein the semiconductor layer is formed of a crystallized semiconductor material, a source electrode electrically connected to the semiconductor layer, and a drain electrode electrically connected to the semiconductor layer, wherein the drain electrode is spaced apart from the source electrode in a first direction and wherein the second conductive patterns at least partially overlap the first conductive pattern and are spaced apart from each other in the first direction.

The second conductive patterns can be formed over the first conductive pattern. The second conductive patterns can be interposed between the substrate and the first conductive pattern. The first conductive pattern and the second conductive patterns can have taper angles which are less than about 70°. The crystallized semiconductor material can comprise polysilicon. The second conductive patterns can be electrically connected to each other via the first conductive pattern. The thin film transistor can further comprise a gate insulation layer interposed between the gate electrode and the semiconductor layer, wherein each of the first conductive pattern and the gate insulation layer has a substantially uniform thickness. A top surface of the gate insulation layer can have a plurality of stepped portions spaced apart from each other. Each of the second conductive patterns can extend in a second direction substantially perpendicular to the first direction. Each of the second conductive patterns can extend in a second direction crossing the first direction.

Another aspect is a display device including a first thin film transistor formed over a substrate and a second thin film transistor electrically connected to the first thin film transistor, wherein the first thin film transistor includes a first gate electrode formed over the substrate and including a first conductive pattern and a plurality of second conductive patterns, a first semiconductor layer formed over the first gate electrode, wherein the first semiconductor layer is formed of a crystallized semiconductor material, a first source electrode electrically connected to the first semiconductor layer, and a first drain electrode electrically connected to the first semiconductor layer, wherein the first drain electrode is spaced apart from the first source electrode in a first direction and wherein the second conductive patterns at least partially overlap the first conductive pattern and are spaced apart from each other in the first direction.

The display device can further comprise a gate line electrically connected to the first gate electrode and a data line electrically connected to the first source electrode. The second thin film transistor can include a second gate electrode formed over the substrate and including a third conductive pattern and a plurality of fourth conductive patterns, a second semiconductor layer formed over the second gate electrode, wherein the second semiconductor layer is formed of the crystallized semiconductor material, a second source electrode electrically connected to the second semiconductor layer, and a second drain electrode electrically connected to the second semiconductor layer, wherein the second drain electrode is spaced apart from the second source electrode in a second direction crossing the first direction and wherein the fourth conductive patterns at least partially overlap the third conductive pattern and are spaced apart from each other. The second semiconductor layer can extend in the second direction and the fourth conductive patterns can be spaced apart from each other in the second direction.

Another aspect is a method of manufacturing a display device including forming a gate electrode over a substrate, wherein the gate electrode has a top surface including at least one stepped portion, forming a gate insulation layer over the substrate so as to at least partially cover the gate electrode, forming an amorphous silicon layer over the gate insulation layer, crystallizing the amorphous silicon layer so as to form a polysilicon layer, partially removing the polysilicon layer so as to form semiconductor layer, forming a source electrode and a drain electrode so as to be electrically connected to the semiconductor layer, wherein the source electrode and the drain electrode are spaced apart from each other in a first direction.

The forming of the gate electrode can include forming a first conductive pattern over the substrate and forming a plurality of second conductive patterns so as to at least partially overlap the first conductive pattern.

Another aspect is a display device including a substrate and a plurality of pixels formed over the substrate, wherein each pixel includes a plurality of thin film transistors and wherein each thin film transistor comprises a gate electrode formed over the substrate and including a first conductive pattern and a plurality of second conductive patterns and a semiconductor layer formed over the gate electrode, wherein the second conductive patterns at least partially overlap the first conductive pattern and are spaced apart from each other.

The thin film transistors of each pixel can include a first thin film transistor and a second thin film transistor, wherein each thin film transistor includes a source electrode and a drain electrode electrically connected to the semiconductor layer, wherein the source and drain electrodes of the first thin film transistor are spaced apart from each other in a first direction, and wherein the second conductive patterns of the first thin film transistor are spaced apart from each other in the first direction. The source and drain electrodes of the second thin film transistor can be spaced apart from each other in a second direction substantially perpendicular to the first direction and the second conductive patterns of the first thin film transistor can be spaced apart from each other in the second direction. The display device can further comprise a plurality of gate lines respectively electrically connected to the pixels, wherein the gate lines are connected to the pixels via one of the respective second conductive patterns.

### BRIEF DESCRIPTION OF THE DRAWINGS

FIG. 1 is a circuit diagram illustrating a pixel circuit of a display substrate in accordance with an embodiment.

FIG. 2 is a plan view illustrating a display substrate in accordance with an embodiment.

FIG. 3 is a cross-sectional view cut along the line I-I′ in FIG. 2 in accordance with an embodiment.

FIG. 4 is a cross-sectional view illustrating the region III in FIG. 3 in accordance with an embodiment.

FIG. 5 is a plan view illustrating a display substrate in accordance with an embodiment.

FIG. 6 is a cross-sectional view cut along the line I-I′ in FIG. 5 in accordance with an embodiment.

FIG. 7 is a plan view illustrating a display substrate in accordance with an embodiment.

FIG. 8 is a cross-sectional view cut along the line I-I′ in FIG. 7 in accordance with an embodiment.

FIG. 9 is a plan view illustrating a display substrate in accordance with an embodiment.

FIG. 10 is a plan view illustrating a display substrate in accordance with an embodiment.

FIG. 11 is a cross-sectional view cut along the line II-II′ in FIG. 10 in accordance with an embodiment.

FIGS. 12 to 20 are plan views and cross sectional views illustrating a method of manufacturing a display substrate in accordance with an embodiment.

FIGS. 21A to 21C are photographs showing crystallized polysilicon of an active pattern depending on channel length.

### DETAILED DESCRIPTION OF CERTAIN INVENTIVE EMBODIMENTS

The standard OLED display includes at least two thin film transistors for each pixel. The thin film transistors act as a switch for an electrical current between source and drain electrodes thereof. A semiconductor layer of each of the thin film transistors can be formed by depositing an amorphous silicon layer and by crystallizing the deposited layer. However, the amorphous silicon layer may be crystallized unevenly.

The example embodiments are described more fully hereinafter with reference to the accompanying drawings. The described technology may, however, be embodied in many different forms and should not be construed as limited to the example embodiments set forth herein. In the drawings, the sizes and relative sizes of layers and regions may be exaggerated for the sake of clarity.

It will be understood that when an element or layer is referred to as being “on,” “connected to,” or “coupled to” another element or layer, it can be directly on, connected, or coupled to the other element or layer or intervening elements or layers may also be present. In contrast, when an element is referred to as being “directly on,” “directly connected to,” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns, and/or sections, these elements, components, regions, layers, patterns, and/or sections should not be limited by these terms. These terms are only used to distinguish one element, component, region, layer, pattern, or section from another region, layer, pattern, or section. Thus, a first element, component, region, layer, or section discussed below could be termed a second element, component, region, layer, or section without departing from the teachings of embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein are to be interpreted accordingly.

The terminology used herein is for the purpose of describing particular example embodiments only and is not intended to be limiting of the described technology. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross sectional illustrations that are schematic illustrations of illustratively idealized example embodiments (and intermediate structures) of the described technology. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the described technology.

Unless otherwise defined, all terms (including technical and scientific terms) used herein have the same meaning as commonly understood by one of ordinary skill in the art to which the described technology belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. The term “substantially” as used in this disclosure can include the meanings of completely, almost completely, or to any significant degree in some applications and in accordance with the understanding of those skilled in the art.

FIG. 1 is a circuit diagram illustrating a pixel circuit of a display substrate or display panel in accordance with an embodiment.

Referring to FIG. 1, the display substrate include a plurality of signal lines and a plurality of sub pixels PX defined by the signal lines and arranged in a matrix.

In example embodiments, the signal lines include a plurality of gate lines GL, a plurality of data lines SL, and a plurality of driving power lines PL.

Each of the sub pixels PX can include at least two thin film transistors, at least one capacitor, and at least one organic light-emitting diode (OLED). In example embodiments, each of the sub pixels PX includes a first thin film transistor Tr1, a second thin film transistor Tr2, a capacitor C1, and an OLED ED.

As shown in FIG. 1, the data line DL is electrically connected to a source electrode of the first thin film transistor Tr1, and the gate line GL is electrically connected to a gate electrode of the first thin film transistor Tr1. Further, a drain electrode of the first thin film transistor Tr1 is electrically connected to the capacitor C1 and a gate electrode of the second thin film transistor Tr2. A source electrode of the second thin film transistor Tr2 is electrically connected to the driving power line PL and a drain electrode of the second thin film transistor Tr2 is electrically connected to the OLED ED.

In example embodiments, the first thin film transistor Tr1 serves as a switching transistor and the second thin film transistor Tr2 serves as a driving transistor. The display substrate is illustrated to include two thin film transistors and one capacitor in FIG. 1; however, the described technology is not limited thereto. For example, in some embodiments, the display substrate includes additional thin film transistors and capacitors.

When the display substrate is used in an OLED display having a relatively large screen, the thin film transistor of the display substrate can be formed with a relatively large channel length in order to improve brightness uniformity of the OLED display.

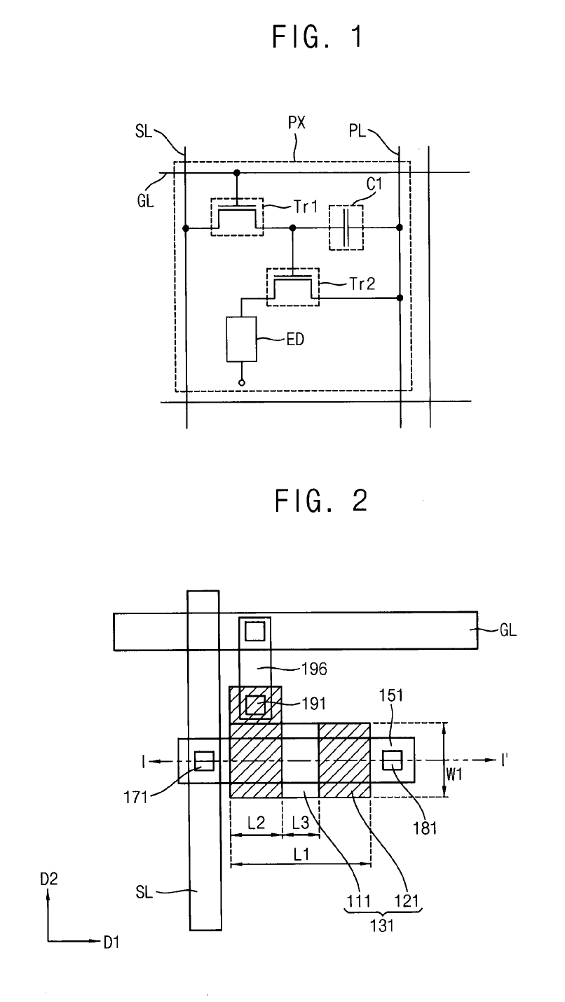

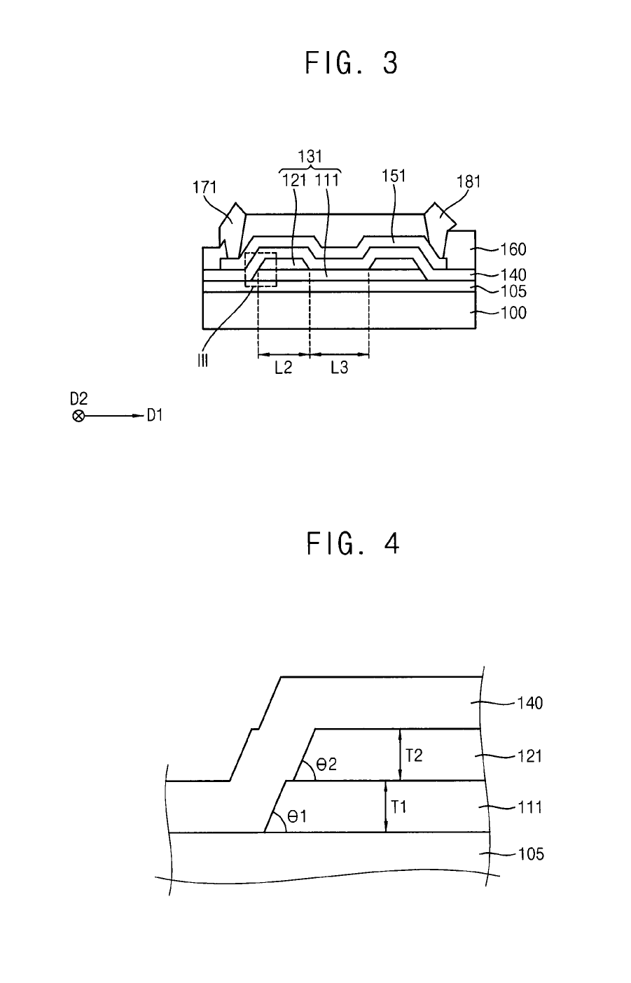

FIG. 2 is a plan view illustrating a display substrate in accordance with an embodiment. FIG. 3 is a cross-sectional view cut along the line I-I′ in FIG. 2. Further, FIG. 4 is a cross-sectional view illustrating the region III in FIG. 3. For the convenience of the explanation, FIG. 2 does not show all elements of the display substrate. That is, some elements thereof, e.g., signal lines, a capacitor, etc. may be omitted in FIG. 2.

Referring to FIGS. 2 and 3, the display substrate in accordance with an embodiment includes a substrate 100, a gate line GL, a data line SL, and a thin film transistor. The thin film transistor includes a gate electrode 131, an active pattern 151, a source electrode 171, and a drain electrode 181. Further, the thin film transistor is electrically connected to the gate line GL through a connection pattern 196 and a contact hole 191.

The substrate 100 can be formed of a transparent insulating material. For example, the substrate 100 may include a glass substrate, a transparent plastic substrate, a transparent ceramic substrate, etc. In other example embodiments, the substrate 100 may include a flexible substrate.

Further, a planarization layer 105 is formed on the substrate 100. The planarization layer 105 can prevent the diffusion of impurities and can form a flat top surface.

The gate electrode 131 is formed on the planarization layer 105. In example embodiments, the gate electrode 131 extends in a first direction substantially parallel to the top surface of the substrate 100. The gate electrode 131 can have a first length L1 in the first direction and a first width W1 in a second direction substantially perpendicular to the first direction. In some embodiments, the first length L1 is greater than the first width W1 and the gate electrode 131 extends in a channel length direction, i.e. in the direction the first length L1 is measured.

In the FIG. 3 embodiment, the gate electrode 131 includes a first conductive pattern 111 and a second conductive pattern 121 which are stacked sequentially.

The first conductive pattern 111 is formed on the planarization layer 105. In example embodiments, the first conductive pattern 111 has a substantially planar shape which is substantially the same as that of the overall gate electrode 131. That is, in some embodiments, the first conductive pattern 111 has a first length L1 in the first direction and a first width W1 in the second direction.

As shown in the embodiments of FIGS. 2 and 3, the second conductive pattern 121 is formed on the first conductive pattern 111. In example embodiments, a plurality of second conductive patterns 121 are formed on one first conductive pattern 111.

In some embodiments, each of the second conductive patterns 121 has a second length L2 in the first direction and a second width which is substantially the same as is less than the first width W1. The second conductive patterns 121 can be spaced apart from each other by a third length L3. In one example embodiment, the third length L3 is substantially less than the second length L2.

The second conductive patterns 121 can be formed on the first conductive pattern 111 such that a stepped portion is formed on a top surface of the gate electrode 131. That is, in some embodiments, the top surface of the first conductive pattern 111 and the top surfaces of the second conductive pattern 121 have different heights.

The first conductive pattern 111 can be formed under the second conductive patterns 121. In some embodiments, the first conductive pattern 111 electrically connect the second conductive patterns 121 which are spaced apart from each other in the first direction. Further, the first conductive pattern 111 can entirely overlap the second conductive pattern 121, so that the first conductive pattern 111 does not degrade the aperture ratio of the display substrate.

Referring to the embodiment of FIG. 4, end portions of the first conductive pattern 111 and the second conductive pattern 121 have relatively small taper angles. The taper angle of the first conductive pattern 111 can be defined as a first angle θ1 and the taper angle of the second conductive pattern 121 can be defined as a second angle θ2. In example embodiments, each of the first and second angles θ1 and θ2 are less than about 70°. In these embodiments, an insulation layer 140 can be formed on the gate electrode 131 to have a substantially uniform thickness.

Further, the first conductive pattern 111 can have a first thickness T1 and the second conductive pattern 121 can have a second thickness T2. In example embodiments, the sum of the first and second thicknesses T1 and T2 is greater than about 8000 Å. In these embodiments, the gate electrode 131 has a relatively low electrical resistance.

If the gate electrode has a single-layer structure, a relatively long time may be required to etch the single gate electrode layer. After etching, the taper angle of the gate electrode may be greater than about 80°. Accordingly, an insulation layer formed on the gate electrode may not have a substantially uniform thickness.

The gate electrode 131 in accordance with example embodiments has a multi-layer structure including the first and second conductive patterns 111 and 121. Etching processes for forming the first and second conductive patterns 111 and 121 can be performed separately. In these embodiments, a relatively short time is required to etch the gate electrode layers. Therefore, the taper angles of the first and second conductive patterns 111 and 121 can be formed to be less than about 70°.

The first and second conductive patterns 111 and 121 may include a conductive metal such as aluminum (Al), molybdenum (Mo), copper (Cu), etc. or a conductive metal oxide such as indium tin oxide (ITO), etc. The first and second conductive patterns 111 and 121 may have an etch selectivity. For example, when the first conductive pattern 111 is formed of ITO, the second conductive pattern 121 can be formed of Mo. In these embodiments, the first conductive pattern 111 is not damaged during an etching process for forming the second conductive patterns 121.

The gate electrode 131 may have a protrusion in the second direction, which may be adjacent to the gate line GL. In example embodiments, the protrusion has a single-layer structure or a multi-layer structure including the first conductive pattern 111 and/or a second conductive pattern 121. The protrusion can directly contact the connection pattern 196 which will be described below.

Referring now to FIGS. 2 and 3, the gate insulation layer 140 is formed on the planarization layer 105 to cover the gate electrode 131. The gate insulation layer 140 has a substantially uniform thickness on the gate electrode 131. According to at least one embodiment, the top surface of the gate electrode 131 has stepped portions due to the second conductive pattern 121, so that the top surface of the gate insulation layer 140 has corresponding stepped portions. In example embodiments, the gate insulation layer 140 may include silicon oxide or silicon nitride. Alternatively, the gate insulation layer 140 may include a high-K dielectric material such as hafnium oxide, zirconium oxide, titanium oxide, etc.

The active pattern or semiconductor layer 151 is formed on the gate insulation layer 140 to overlap the gate electrode 131. In some embodiments, the active pattern 151 extends in the first direction. In example embodiments, the active pattern 151 has a length which is greater than the first length L1 of the gate electrode 131 and has a width which is less than the first width W1 of the gate electrode 131.

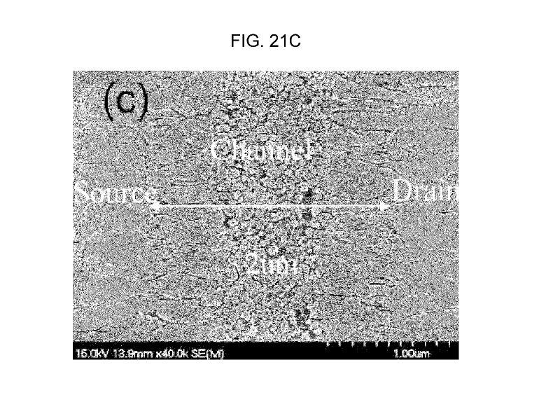

The active pattern 151 may include a crystallized semiconductor material. For example, the active pattern 151 may include a polysilicon formed by crystallizing amorphous silicon. In some embodiments, the crystallization of the amorphous silicon starts from the stepped portions of the top surface of the gate insulation layer 140. That is, the stepped portions of the top surface of the gate insulation layer 140 can serve as crystallization starting points. By forming the second conductive patterns 121 on the first conductive pattern 111, the distance between adjacent stepped portions formed under the active pattern 151 decreases. Therefore, the distance between adjacent crystallization starting points decreases, even as the length of the gate electrode 131 in the first direction increases. Accordingly, the polysilicon which can be formed by crystallizing amorphous silicon can be formed to have a substantially uniform grain size. The grain size of the polysilicon which can depend on the distance between crystallization starting points will be described with reference to FIG. 21. Further, the active pattern 151 can have substantially uniform electrical characteristics due to the substantially uniform grain size.

The active pattern 151 includes impurity regions (not shown). In example embodiments, the impurity regions directly contact the source electrode 171 or the drain electrode 181, thereby reducing electrical contact resistance.

In example embodiments, the thin film transistor has a bottom gate structure in which the gate electrode 131 is interposed between the substrate 100 and the active pattern 151.

An insulation layer 160 is formed on the gate insulation layer 140 to cover the active pattern 151. For example, the insulation layer 160 may include silicon oxide.

The source electrode 171 directly contacts one portion of the active pattern 151 via a contact hole formed in the insulation layer 160. The drain electrode 181 directly contacts another portion of the active pattern 151 via another contact hole formed in the insulation layer 160. In example embodiments, the source and drain electrodes 171 and 181 are spaced apart from each other in the first direction. Further, the source and drain electrodes 171 and 181 may include a metal or a conductive metal oxide.

Referring now to FIG. 2, the gate line GL can be formed on the planarization layer 105 and extends in the first direction. In example embodiments, the gate line GL has a single-layer structure or a multi-layer structure including materials which may be the same as those of the first conductive pattern 111 and/or a second conductive pattern 121. That is, in some embodiments, the gate line GL has a height which is substantially the same as that of the gate electrode 131. In example embodiments, a plurality of gate lines are arranged in the second direction.

Further, the gate line GL and the gate electrode 131 are electrically connected via the connection pattern 196. The connection pattern 196 can be formed to contact the gate line GL and the gate electrode 131 via contact holes formed in the insulation layer 160.

On the other hand, the data line SL can be formed on the insulation layer 160 and extends in the second direction. In example embodiments, the data line SL is electrically connected to the source electrode 171.

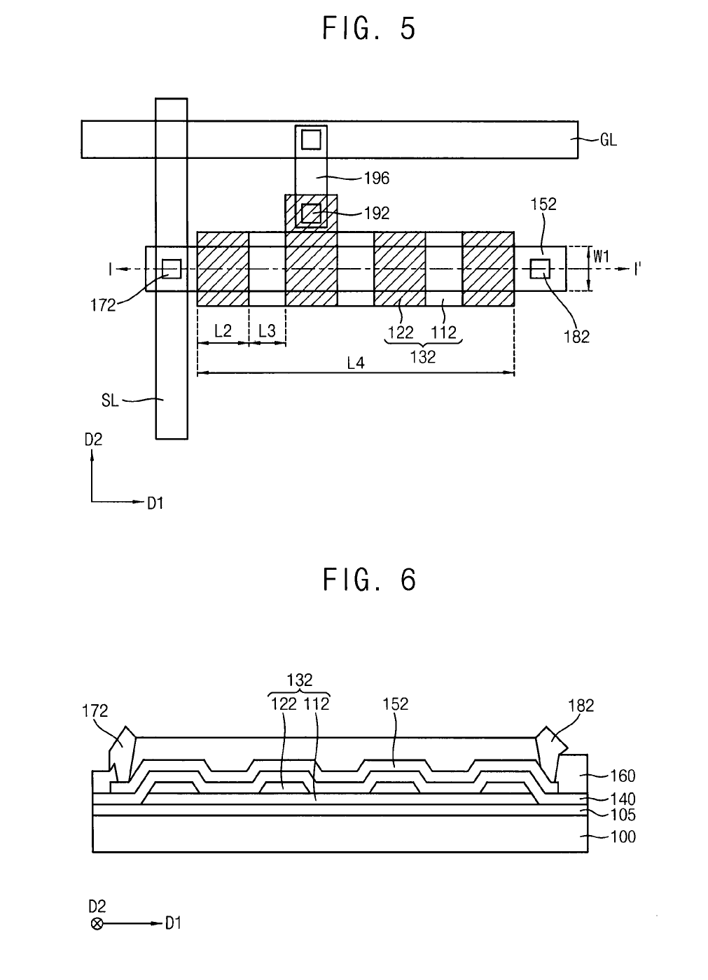

Referring to FIGS. 5 and 6, the display substrate in accordance with an embodiment includes a substrate 100, a gate line GL, a data line SL, and a thin film transistor. The thin film transistor includes a gate electrode 132, an active pattern 152, a source electrode 172, and a drain electrode 182. The thin film transistor of the embodiment of FIGS. 5 and 6 is substantially the same as or similar to the thin film transistor described in FIGS. 2 to 4 except for the gate electrode 132.

The gate electrode 132 has a fourth length L4 in the first direction and a first width W1 in a second direction substantially perpendicular to the first direction. In example embodiments, the fourth length L4 is at least three times greater than the first width W1.

The gate electrode 132 includes a first conductive pattern 112 and second conductive patterns 122 which are stacked sequentially. In example embodiments, a plurality of second conductive patterns 122 are formed on the first conductive pattern 112. For example, four second conductive patterns 122 can be formed on one first conductive pattern 112 as illustrated in FIGS. 5 and 6. However, the described technology is not limited to the number of the second patterns 122 illustrated in the embodiment of FIGS. 5 and 6. For example, two to ten second conductive patterns 122 can be formed on one first conductive pattern 112 in other embodiments.

Each of the second conductive patterns 122 can have a second length L2 in the first direction. The second conductive patterns 122 can be spaced apart from each other by a third length L3. As the length of the gate electrode 132 increases, the number of the second conductive pattern 122 can increase accordingly.

According to example embodiments, by forming the second conductive patterns 122 on the first conductive pattern 112, the distance between adjacent stepped portions decreases. Therefore, the distance between adjacent crystallization starting points decreases for the crystallization of the active pattern 152. That is, according to at least one embodiment, the stepped portions formed by the second conductive pattern 122 serve as crystallization starting points.

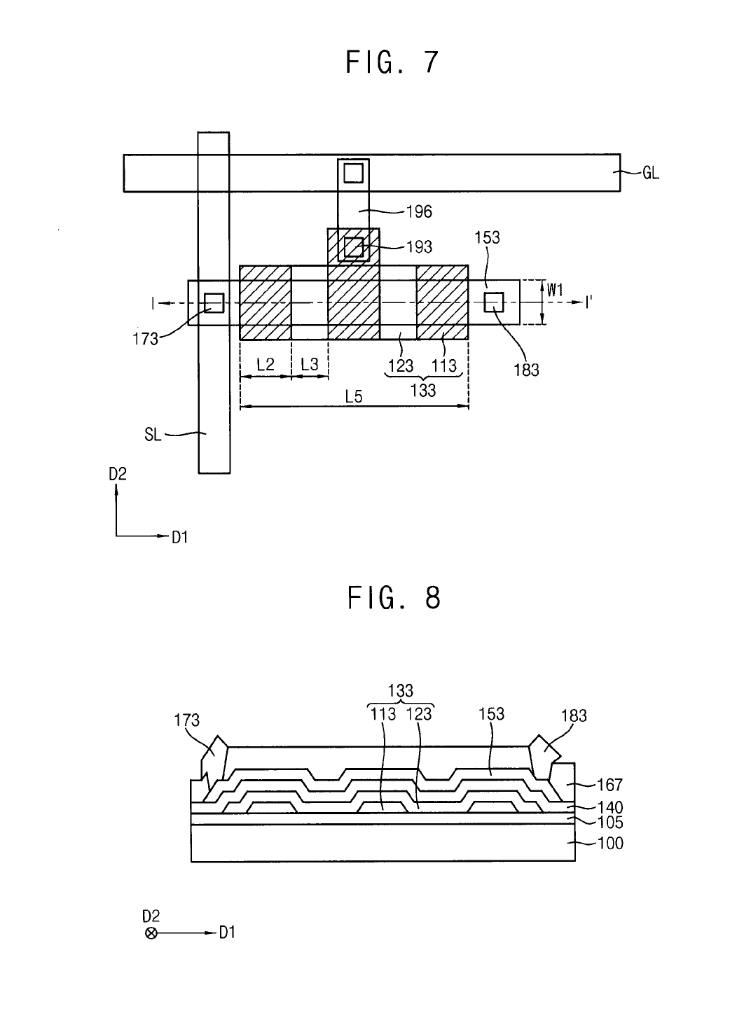

Referring to FIGS. 7 and 8, the display substrate in accordance with an embodiment includes a substrate 100, a gate line GL, a data line SL, and a thin film transistor. The thin film transistor includes a gate electrode 133, an active pattern 153, a source electrode 173, and a drain electrode 183. The thin film transistor is substantially the same as or similar to the thin film transistor described in FIGS. 2 to 4 except for the gate electrode 133.

In the embodiment of FIGS. 7 and 8, the gate electrode 133 includes first conductive patterns 113 and a second conductive pattern 123 which are stacked sequentially.

In example embodiments, a plurality of first conductive patterns 113 are formed on the planarization layer 105. The first conductive patterns 113 are arranged in a first direction and each of the first conductive patterns 113 extends in a second direction which is substantially perpendicular to the first direction. Further, the second conductive pattern 123 is formed to cover the first conductive patterns 113. The second conductive pattern 123 has a substantially uniform thickness, so that a top surface of the gate electrode 133 can be formed to have stepped portions.

When performing an etching process for forming the second conductive pattern 123, the first conductive patterns 113 can be prevented from being exposed to an etching solution. Therefore, the materials of the first and second conductive patterns 113 and 123 are not required have an etch selectivity in this embodiment.

Three first conductive patterns 113 are formed in the embodiment illustrated in FIGS. 7 and 8. However, the described technology is not limited to the number of the first conductive patterns 113 illustrated in the embodiment of FIGS. 7 and 8. For example, two to ten first conductive patterns 113 can be formed as necessary, depending on the embodiment.

Since the first conductive patterns 113 are formed under the second conductive pattern 123 in the embodiment of FIGS. 7 and 8, the top surfaces of the gate electrode 133 and the gate insulation layer 140 can be formed to have stepped portions. The stepped portions formed by the first conductive patterns 113 can serve as crystallization starting points. Therefore, the distance between adjacent crystallization starting points decreases for the crystallization of the active pattern 153. Accordingly, the active pattern 153 can be formed to have a substantially uniform grain size.

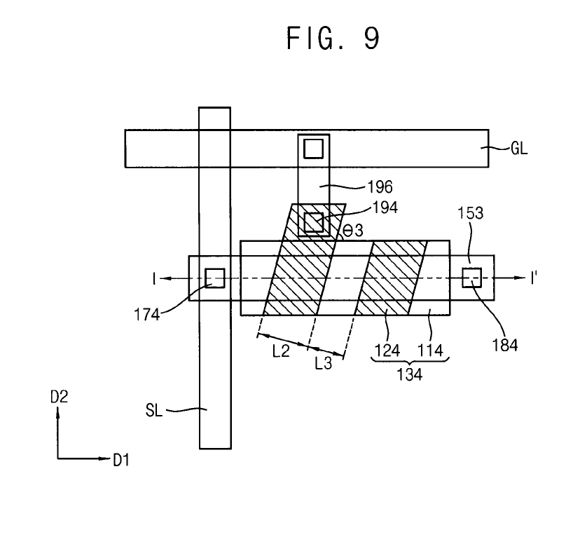

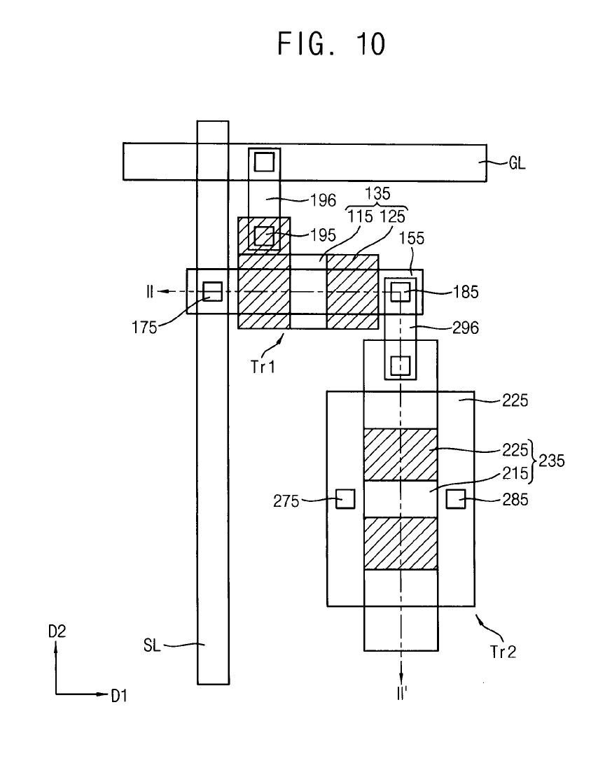

FIG. 9 is a plan view illustrating a display substrate in accordance with an embodiment.

Referring to FIG. 9, the thin film transistor of the display substrate is substantially the same as or similar to the thin film transistor described in FIGS. 2 to 4 except for the gate electrode 134.

The gate electrode 134 includes a first conductive pattern 114 and second conductive patterns 124 which are stacked sequentially.

In example embodiments, a plurality of second conductive patterns 124 are formed to be spaced apart from each other in a first direction. In this embodiment, each of the second conductive patterns 124 extends in a third direction. In example embodiments, the third direction is oblique to the first direction. For example, the third angle θ3 between the first direction and the third direction can be about 45°. Therefore, stepped portions can be formed on the top surface of the gate electrode 134 arranged in the oblique direction. The stepped portions formed by the second conductive patterns 124 can serve as crystallization starting points for forming an active pattern 154. Since in some embodiments, the second conductive patterns 124 extend in the third direction, the locations of the crystallization starting points are varied in these embodiments with respect to embodiments where the second conductive patterns extend in the second direction.

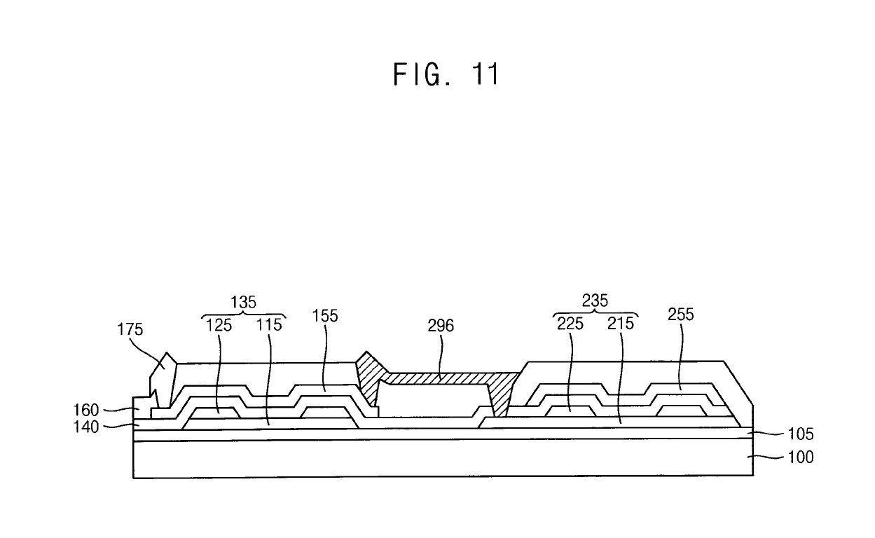

Referring to FIGS. 10 and 11, the display substrate in accordance with an embodiment includes a substrate 100, a gate line GL, a data line SL, a first thin film transistor Tr1, and a second thin film transistor Tr2. In example embodiments, the first and second thin film transistors Tr1 and Tr2 constitute a pixel circuit as described with reference to FIG. 1. That is, in these embodiments, the first thin film transistor Tr1 serves as a switching transistor and the second thin film transistor Tr2 serves as a driving transistor.

The first thin film transistor Tr1 include a first gate electrode 135, a first active pattern 155, a first source electrode 175, and a first drain electrode 185. In example embodiments, the first thin film transistor Tr1 is substantially the same as or similar to the thin film transistors described with reference to FIGS. 2 to 4, FIGS. 5 and 6, FIGS. 7 and 8, or FIG. 9.

In some embodiments, the second thin film transistor Tr2 includes a second gate electrode 235, a second active pattern 255, a second source electrode 275, and a second drain electrode 285.

In example embodiments, the second gate electrode 235 extends in a second direction. That is, the length of the second gate electrode 235 in the second direction is substantially greater than the width of the second gate electrode 235 in the first direction.

Further, as illustrated in the embodiment of FIG. 10, the second gate electrode 235 includes a third conductive pattern 215 and a plurality of fourth conductive patterns 225. The third conductive pattern 215 has a substantially planar shape which is substantially the same as that of the second gate electrode 235. The fourth conductive patterns 225 are formed on the third conductive pattern 215. Each of the fourth conductive patterns 225 are spaced apart from each other in the second direction. Due to the formation of the fourth conductive patterns 225 in the embodiment of FIG. 10, the top surface of the second gate electrode 235 has stepped portions.

The second active pattern 255 is formed on the gate insulation layer 140 overlapping the second gate electrode 235. For example, the second active pattern 255 may include polysilicon which may be formed by crystallizing amorphous silicon. In some embodiments, the stepped portions of the top surface of the gate insulation layer 140 serves as crystallization starting points. Since the fourth conductive patterns 225 are formed on the third conductive pattern 215, the distance between adjacent stepped portions decreases compared to when no fourth conductive patterns 225 are formed. Therefore, according to at least one embodiment, the distance between adjacent crystallization starting points decreases, even as the length of the second gate electrode 235 in the second direction increases. Accordingly, the polysilicon which may be formed by crystallizing amorphous silicon can be formed to have a substantially uniform grain size.

Alternatively, the length of the second gate electrode 235 in the second direction can be substantially less than the width of the second gate electrode 235 in the first direction. In this embodiment, the fourth conductive patterns 255 are spaced apart from each other in the first direction.

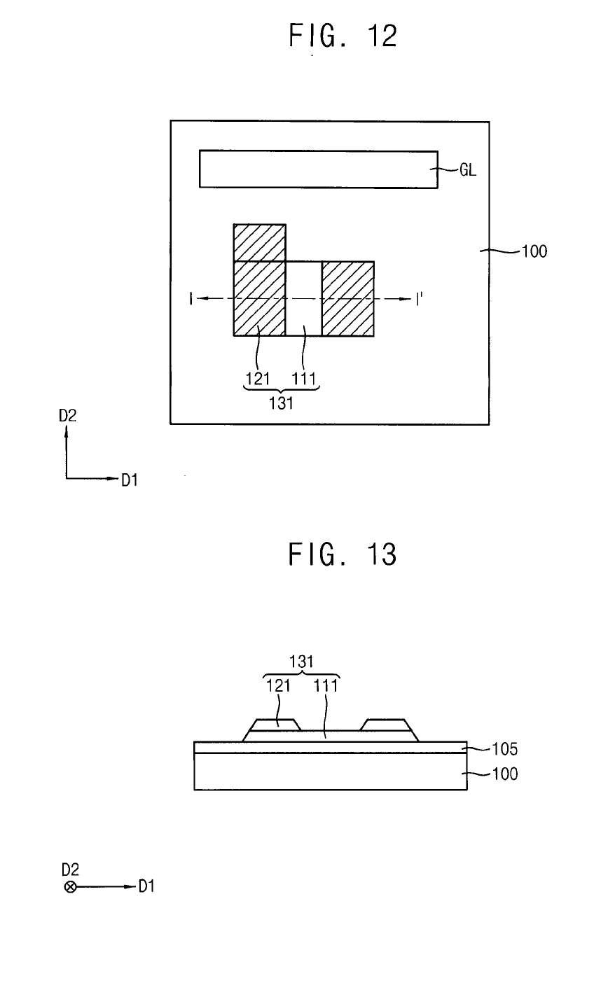

FIGS. 12 to 20 are plan views and cross sectional views illustrating a method of manufacturing a display substrate in accordance with an embodiment.

Referring to FIGS. 12 and 13, a gate electrode 131 and a gate line GL are formed on a substrate.

After forming a planarization layer 105 on the substrate 100, a first conductive layer is formed on the planarization layer 105 and the first conductive layer is patterned to form a first conductive pattern 111. Then, a second conductive layer is formed to cover the first conductive pattern 111 and the second conductive layer is patterned to form second conductive patterns 121 and the gate line GL.

Thereafter, the first and second conductive patterns 111 and 121 constitute the gate electrode 131. In example embodiments, the second conductive patterns 121 are spaced apart from each other so that the top surface of the gate electrode 131 has stepped portions.

Further, the gate line GL is spaced apart from the gate electrode 131. The gate line GL can have a single-layer structure or a multi-layer structure including materials which may be substantially the same as those of the first conductive pattern 111 and/or a second conductive pattern 121.

In some embodiments, the first and second conductive patterns 111 and 121 have an etch selectivity. For example, when the first conductive pattern 111 is formed of TTO, the second conductive pattern 121 can be formed of Mo. In these embodiments, the first conductive pattern 111 is not damaged during an etching process for forming the second conductive patterns 121.

In example embodiments, the sum of the first thickness T1 and the second thickness T2 is greater than about 8000 Å. Therefore, the gate electrode 131 has a relatively low electrically resistance.

If the gate electrode has a single-layer structure, a relatively long time may be required to etch the single gate electrode layer. Therefore, the taper angle of the gate electrode may be greater than about 80°. Accordingly, an insulation layer formed on the gate electrode may not have a uniform thickness.

The gate electrode 131 in accordance with example embodiments has a multi-layer structure including the first conductive pattern 111 and the second conductive patterns 121. An etching process for forming the first conductive pattern 111 and an etching process for forming the second conductive pattern 121 can be performed separately. Therefore, a relatively short time may be required to etch the gate electrode layers. Therefore, the taper angles of the first and second conductive patterns 111 and 121 can be less than about 70°.

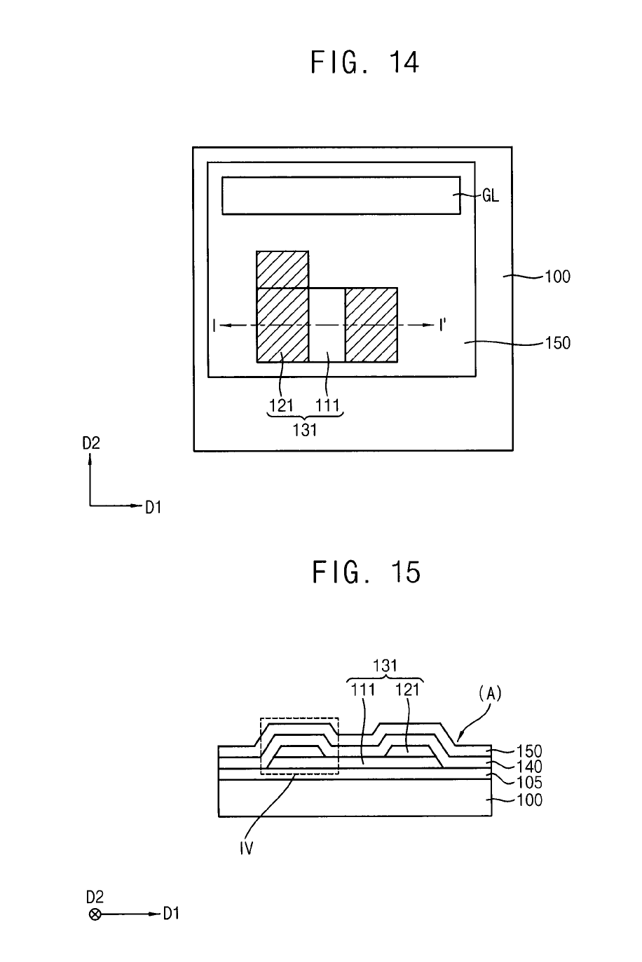

Referring to FIGS. 14 to 16, a gate insulation layer 140 and an amorphous silicon layer are formed to cover the gate electrode 131 and the gate line GL and then the amorphous silicon layer is crystallized to form a polysilicon layer 150.

In example embodiments, the gate insulation layer 140 and the amorphous silicon layer have substantially uniform thicknesses. Since in these embodiments the top surface of the gate electrode 131 has stepped portions, the top surfaces of the gate insulation layer 140 and the amorphous silicon layer also have stepped portions.

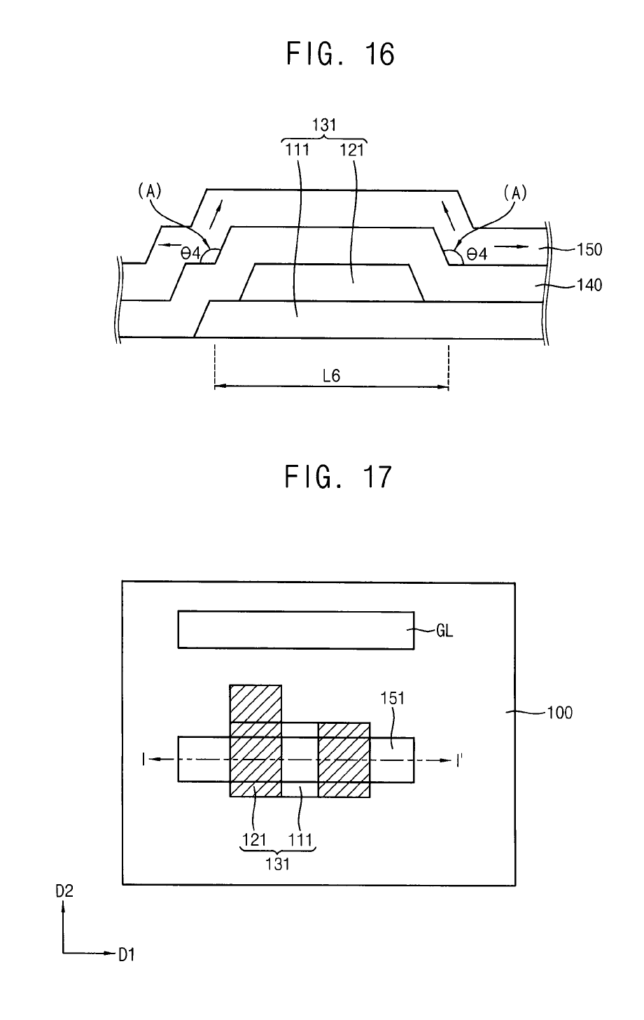

FIG. 16 is a cross-sectional view illustrating region IV in FIG. 15. Referring to FIG. 16, the crystallization process can include scanning a laser beam over the amorphous silicon layer. In the embodiment of FIG. 16, the stepped portions of the top surface of the gate insulation layer 140 have a fourth angle θ4 which is less than about 180° and the other portions of the top surface of the gate insulation layer 140 have an angle which is substantially the same as or greater than about 180°. In this embodiment, the stepped portions of the top surface of the gate insulation layer 140 serve as crystallization starting points (A). Accordingly, the crystallization can progress in a direction toward the second conductive pattern 121 and an opposite direction.

If the distance between adjacent crystallization starting points (A) is greater than a predetermined distance, small size grains may be generated in a region between adjacent crystallization starting points (A). Therefore, the polysilicon layer may not have a uniform grain size (See FIG. 21C).

If the distance between adjacent crystallization starting points (A) is substantially equal to less than the predetermined distance, the length or the width of a channel of the thin film transistor cannot be altered to be greater than the predetermined distance when a single-layer structure gate electrode is employed.

According to at least one embodiment, the gate electrode 131 includes the second conductive pattern 121 which are spaced apart from each other. Even when the length or the width of a channel of the thin film transistor increases, the distance between adjacent crystallization starting points (A) can be fixed to at most a predetermined distance L6. Accordingly, the polysilicon layer 150 can have a substantially uniform grain size (See FIG. 21A).

Referring to FIGS. 17 and 18, the polysilicon layer 150 is partially removed to form an active pattern 151.

The active pattern 151 substantially overlaps the gate electrode 131. The active pattern 151 include impurity regions (not shown). In example embodiments, the impurity regions directly contact the source electrode 171 and/or the drain electrode 181, thereby reducing electrical contact resistance.

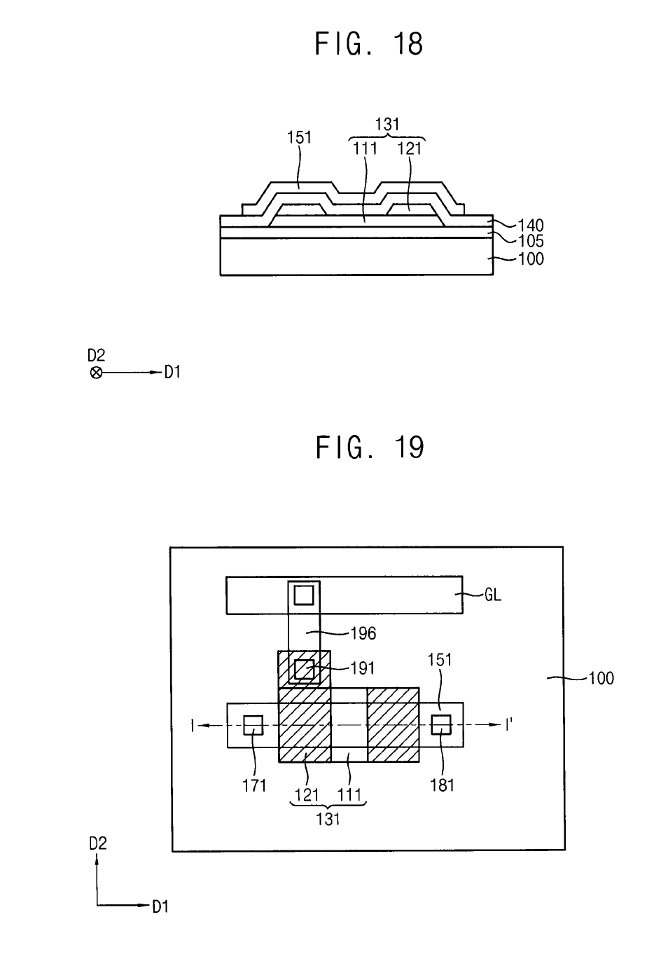

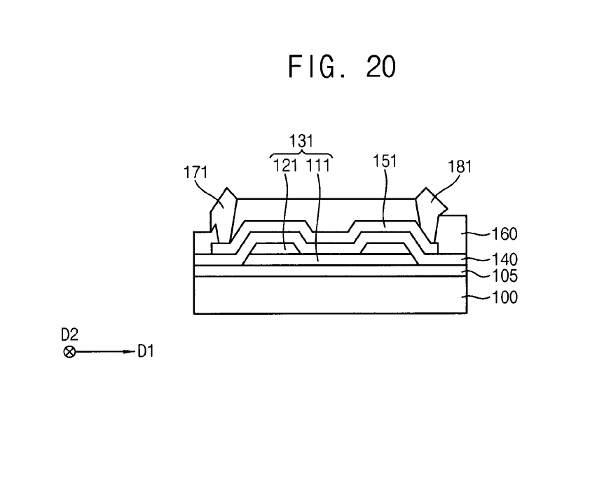

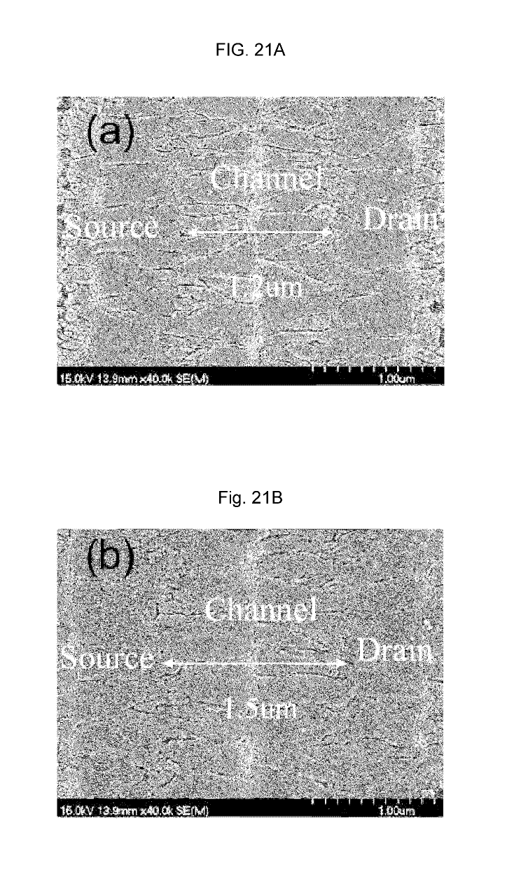

Referring to FIGS. 19 and 20, an insulation layer is formed to cover the active pattern 151 and then a source electrode 171 and a drain electrode 181 are formed. Each of the source and drain electrodes 171 and 181 contacting the active pattern 151 via contact holes formed in the insulation layer 160.

FIG. 21 illustrates photographs showing crystallized polysilicon of an active pattern based on a channel length.

Gate electrodes having a single-layer structure and having different widths were formed on a plurality of substrates. An amorphous silicon layer and a gate insulation layer were formed to cover the gate electrodes. Then, a laser beam was irradiated onto the amorphous silicon layer, thereby crystallizing the amorphous silicon layer. The microstructure of the polysilicon layer is observed in the photographs of FIG. 21.

FIG. 21A is a photograph showing a crystallized polysilicon when the width of the gate electrode is about 1.2 μm. FIG. 21B is a photograph showing a crystallized polysilicon when the width of the gate electrode is about 1.5 μm. FIG. 21C is a photograph showing a crystallized polysilicon when the width of the gate electrode is about 2 μm.

The top surface of the gate insulation layer had stepped portions due to end portions of the gate electrode. The stepped portions may serve as crystallization starting points. In the photographs of FIGS. 21A and 21B, the polysilicon layer have a substantially uniform grain size. Referring to FIG. 21C, the polysilicon layer does not have a uniform grain size. That is, small sized grains are generated in a central region between adjacent crystallization starting points.

Accordingly, the polysilicon layer does not have a uniform grain size when the distance between adjacent crystallization starting points (A) is larger than a predetermined distance.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of the example embodiments as defined in the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the specific embodiments disclosed, and that modifications to the disclosed example embodiments, as well as other example embodiments, are intended to be included within the scope of the appended claims. The invention is defined by the following claims, with equivalents of the claims to be included therein.

What is claimed is:

1. A thin film transistor for a display device, comprising:
a gate electrode formed over a substrate and including a first conductive pattern and a plurality of second conductive patterns;
a semiconductor layer formed over the gate electrode, wherein the semiconductor layer is formed of a crystallized semiconductor material;
a source electrode electrically connected to the semiconductor layer; and
a drain electrode electrically connected to the semiconductor layer, wherein the drain electrode is spaced apart from the source electrode in a first direction, and
wherein the second conductive patterns at least partially overlap the first conductive pattern and are spaced apart from each other in the first direction.

2. The thin film transistor of claim 1, wherein the second conductive patterns are formed over the first conductive pattern.

3. The thin film transistor of claim 1, wherein the second conductive patterns are interposed between the substrate and the first conductive pattern.

4. The thin film transistor of claim 1, wherein the first conductive pattern and the second conductive patterns have taper angles which are less than about 70°.

5. The thin film transistor of claim 4, wherein the crystallized semiconductor material comprises polysilicon.

6. The thin film transistor of claim 1, wherein the second conductive patterns are electrically connected to each other via the first conductive pattern.

7. The thin film transistor of claim 1, further comprising a gate insulation layer interposed between the gate electrode and the semiconductor layer, wherein each of the first conductive pattern and the gate insulation layer has a substantially uniform thickness.

8. The thin film transistor of claim 7, wherein a top surface of the gate insulation layer has a plurality of stepped portions spaced apart from each other.

9. The thin film transistor of claim 1, wherein each of the second conductive patterns extends in a second direction substantially perpendicular to the first direction.

10. The thin film transistor of claim 1, wherein each of the second conductive patterns extends in a second direction crossing the first direction.

11. A display device, comprising:
a first thin film transistor formed over a substrate; and
a second thin film transistor electrically connected to the first thin film transistor,
wherein the first thin film transistor includes:
a first gate electrode formed over the substrate and including a first conductive pattern and a plurality of second conductive patterns;
a first semiconductor layer formed over the first gate electrode, wherein the first semiconductor layer is formed of a crystallized semiconductor material;
a first source electrode electrically connected to the first semiconductor layer; and
a first drain electrode electrically connected to the first semiconductor layer, wherein the first drain electrode is spaced apart from the first source electrode in a first direction,
wherein the second conductive patterns at least partially overlap the first conductive pattern and are spaced apart from each other in the first direction.

12. The display device of claim 11, further comprising:
a gate line electrically connected to the first gate electrode; and
a data line electrically connected to the first source electrode.

13. The display device of claim 11, wherein the second thin film transistor includes:
a second gate electrode formed over the substrate and including a third conductive pattern and a plurality of fourth conductive patterns;
a second semiconductor layer formed over the second gate electrode, wherein the second semiconductor layer is formed of the crystallized semiconductor material;
a second source electrode electrically connected to the second semiconductor layer; and
a second drain electrode electrically connected to the second semiconductor layer, wherein the second drain electrode is spaced apart from the second source electrode in a second direction crossing the first direction, and
wherein the fourth conductive patterns at least partially overlap the third conductive pattern and are spaced apart from each other.

14. The display device of claim 13, wherein the second semiconductor layer extends in the second direction and wherein the fourth conductive patterns are spaced apart from each other in the second direction.

15. A method of manufacturing a display device, comprising:
forming a gate electrode over a substrate, wherein the gate electrode has a top surface including at least one stepped portion;
forming a gate insulation layer over the substrate so as to at least partially cover the gate electrode;
forming an amorphous silicon layer over the gate insulation layer;
crystallizing the amorphous silicon layer so as to form a polysilicon layer;
partially removing the polysilicon layer so as to form semiconductor layer;
forming a source electrode and a drain electrode so as to be electrically connected to the semiconductor layer, wherein the source electrode and the drain electrode are spaced apart from each other in a first direction.

16. The method of claim 15, wherein the forming of the gate electrode includes:
forming a first conductive pattern over the substrate; and
forming a plurality of second conductive patterns so as to at least partially overlap the first conductive pattern.

17. A display device, comprising:
a substrate; and
a plurality of pixels formed over the substrate, wherein each pixel includes a plurality of thin film transistors and wherein each thin film transistor comprises:
a gate electrode formed over the substrate and including a first conductive pattern and a plurality of second conductive patterns; and
a semiconductor layer formed over the gate electrode,
wherein the second conductive patterns at least partially overlap the first conductive pattern and are spaced apart from each other.

18. The display device of claim 17, wherein the thin film transistors of each pixel include a first thin film transistor and a second thin film transistor, wherein each thin film transistor includes a source electrode and a drain electrode electrically connected to the semiconductor layer, wherein the source and drain electrodes of the first thin film transistor are spaced apart from each other in a first direction, and wherein the second conductive patterns of the first thin film transistor are spaced apart from each other in the first direction.

19. The display device of claim 18, wherein the source and drain electrodes of the second thin film transistor are spaced apart from each other in a second direction substantially perpendicular to the first direction, and wherein the second conductive patterns of the first thin film transistor are spaced apart from each other in the second direction.

20. The display device of claim 17, further comprising a plurality of gate lines respectively electrically connected to the pixels, wherein the gate lines are connected to the pixels via one of the respective second conductive patterns.
